(19) United States
(12) Patent Application Publication
(10) Pub. No.: US 2004/0090746 A1
(43) Pub. Date: May 13, 2004

(54) Cooling device for a computer

(76) Inventor: Hannes Reisacher, Kempten (DE)

Correspondence Address: Perkins Coie, PO Box 2168, Menlo Park, CA, 94026, US

(21) Appl. No.: 10/332,462

(22) PCT Filed: Jul. 5, 2001
(86) PCT No.: PCT/EP01/07707

(30) Foreign Application Priority Data
Jul. 5, 2000 (DE) 100320503

(51) Int. Cl. H05K 7/20

(52) U.S. Cl. 361/714

(57) ABSTRACT

According to the invention, a simple and reliable cooling device for a computer, comprising a processor (4), mounted on a main board (5), the temperature of which may be maintained at a temperature below ambient, in particular at a negative temperature, by means of an active cooling unit (3), may be achieved, whereby the processor (4) and the main board (5) are placed in a cooled box (6), made from a micro-porous pressed ceramic powder based on a metal oxide, in particular, pyrogenically-created highly-dispersed silicic acid or silicon aerogel.

### CROSS-REFERENCE

This application claims priority under 35 U.S.C. § 120 to prior-filed PCT Application PCT/EP01/07707, entitled “Cooling Device for a Computer”, and having a filing date of Jul. 5, 2001. This application further claims priority under 35 U.S.C. § 119 to prior-filed German Application No. 10,032,050, entitled “Cooling Device for a Computer”, and having a filing date of Jul. 5, 2000.

### FIELD

The invention relates to a cooling apparatus for computers, comprising a processor mounted on a motherboard, which processor can be cooled to temperatures below ambient temperatures, in particular negative temperatures, by means of an active cooling unit.

### BACKGROUND

In order to cool computers, and especially the processor (CPU), there are active cooling units in addition to cooling by means of heatsinks and a blower mounted thereon, which active cooling units can cool the processor temperature to below ambient temperature. For example, water cooling systems or other coolants are used for this purpose which are circulated by means of pumps or heat exchangers. These active cooling units allow achievement of temperatures far below 0° C., so that the processor and connected switching elements which are often based on CMOS technology in particular can be operated at such temperatures with considerably higher clock speeds.

The disadvantage in the aforementioned cooling units is the likelihood that in the case of a burst hose between the CPU and the cooling unit the coolant can cause considerable damage up to a total breakdown of the computer. Moreover, the direct dissipation of the heat on the processor is very complex because the coolant places considerable requirements on the seals of the current-bearing components.

What is needed is a cooling apparatus for computers which is arranged in a simple and more secure fashion.

### SUMMARY

A cooling apparatus for computers, with a processor attached to a motherboard, which processor can be cooled off by way of an active cooling unit to temperatures below ambient temperature, especially negative temperatures, characterized in that the processor (4) and the motherboard (5) are inserted in a cooling box (6) made of micro-porous pressed ceramic powder on a base of metal oxides, in particular pyrogenically produced, highly dispersed silicic acid or silicon aerogel.

By introducing the processor together with its motherboard (motherboard) into a cooling box it is not necessary to conduct any configuration work directly on the motherboard or the processor. In this way the motherboard can be inserted in a substantially unchanged fashion into the cooling box. It is merely necessary to lead the cables outwardly to the peripheral devices such as power unit, drives, etc. The relevant aspect is in this respect that by providing the cooling box of micro-porous pressed ceramic powder on a base of metal oxides, and in particular highly dispersed silicic acid or silicon aerogels, a highly improved insulation capability is achieved because such materials achieve a very low thermal conductibility of only approx. 0.01 W/mK or below. This effect is improved even further when such insulating materials are evacuated, e.g. to negative pressures of 1-10 mbar. For this purpose the pressed composite insulation part is packed into a casing which is as air-tight or diffusion-tight as possible in order to maintain the degree of evacuation over a long period of time.

As a result of the exceptional insulation properties of this material, already a very low drive output of the active cooling unit is sufficient for circulation. Note that air or any other gas is used instead of the coolant liquids used otherwise, so that even in the case of hose breakages there will not be any damage to the electronic systems. Moreover, by using air or other gases (e.g. nitrogen) which is cooled to approx. −30° C. the complexity of assembling the cooling unit is reduced substantially. Preferably, a dehumidifier is provided in the cooling unit to avoid water condensation.

The proposed cooling box consists in a preferred embodiment of two half-shells forming an inner hollow space in which the motherboard is inserted together with the processor (CPU). As a result it is merely necessary to cool this inside space with an inside volume of approx. one liter for example. In this case it is preferable to also house the RAMs (memory) and the like in addition to the motherboard and the processor, so that they can also be operated at higher clock speeds at negative temperatures. The two half-shells of the cooling box are preferably arranged in a symmetrical fashion in order to simplify production. The half-shells are preferably joined by way of film hinges or hooks or clips, with the film hinge for example preferably being formed by projecting parts of a bag-like casing for the insulating micro-porous ceramic powder.

The cooling box is further provided with at least one outlet opening for the required cables such as the data lines to the drives or the supply leads of the network. In order to avoid thermal losses, the outlet opening is preferably provided with a wavelike cross section which is also closed off in a relatively air-tight manner by means of several sealing rims. As already explained above, the micro-porous pressed ceramic powder on a base of metal oxides is preferably enclosed in a casing and evacuated in order to further reduce thermal conductibility. Furthermore, the casing is used for the secure enclosing of the microporous ceramic powder, and the micro-dispersed silicic acid in particular, so that no dust particles can reach the electronic components.

### BRIEF DESCRIPTION OF THE DRAWINGS

An embodiment will be explained below in closer detail by reference to the enclosed drawings, wherein:

FIG. 1 shows a schematic perspective view of a computer with a cooling apparatus, and

FIG. 2 shows an enlarged sectional view of a cooling box.

### DETAILED DESCRIPTION

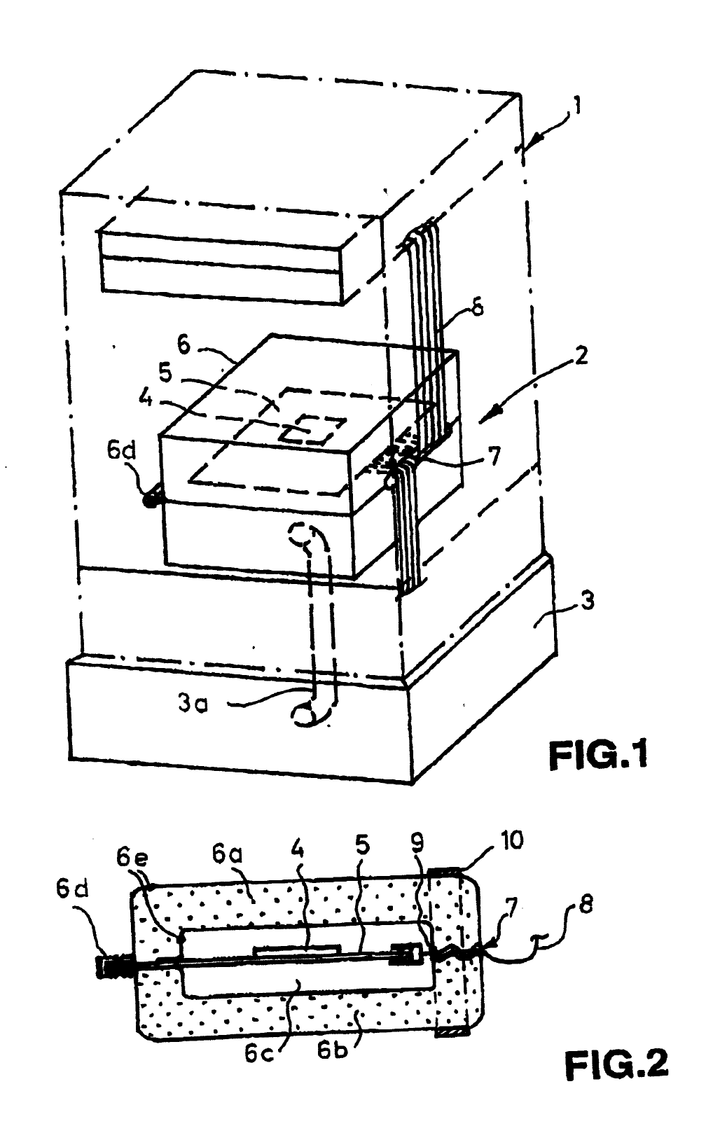

FIG. 1 shows a computer housing 1 in dot-dash lines. This computer housing 1 includes in addition to a power unit as shown below and a drive as shown above, at least one motherboard 5 and a processor 4 which is situated thereon. The drive situated at the top or the power unit situated at the bottom for example are connected to the motherboard (motherboard) 5 by means of a plurality of cables 8, especially in the form of ribbon cables. At least the processor 4 and the motherboard 5 (as well as optionally other electronic components) are housed in a cooling box 6 which in combination with a cooling unit 3 forms the cooling apparatus for the computer. The cooling unit 3 is arranged here schematically on the base of the computer housing 1 and is connected with the cooling box 6 by way of a heat-insulated hose 3a.

As can be seen in particular from the sectional view of cooling box 6 in FIG. 2, the cooling box 6 consists of two half-shells 6a, 6b which form an inner hollow space 6c. The motherboard 5 with the CPU arranged thereon is inserted into the inner hollow space. The half-shells are preferably provided with a symmetrical arrangement and are connected with each other via a film hinge 6d. It is also possible to provide externally enclosing hooks or clips 10 in order to connect the two half-shells 6a and 6b. The film hinge 6d is preferably formed by the projecting parts of a casing 6e which encloses the substantially micro-porous pressed ceramic powder on a base of metal oxides, in particular highly dispersed silicic acid or silicon oxide aerogels. The microporous ceramic powder, which is shown in dots, can optionally be laced with hardener and/or fiber additives as well as opacifiers (e.g. ilmenite). In this way these silicic acides with a BET surface area of several hundred square meters per gram achieve excellent low thermal conductivity values. They can be improved even further by evacuation in that the microporous ceramic powder is placed after pressing in a bag-like plastic casing 6e. The casing 6e is preferably provided with an arrangement which is diffusion-tight.

A slot-like outlet opening 7 is provided in the cooling box 6 so as to pass through the required cabling 8 from the motherboard 5 to the peripheral components such as the power unit, drives and the like. In order to achieve the best possible sealing, the outlet opening 7 is provided with a wave-like cross section, with sealing rims 9 being provided at least on the inner side facing the hollow space 6c. In this way it is possible to reduce the thermal and refrigeration loss at the outlet opening 7 to a substantial extent, so that the power requirements of the active cooling unit 3 on the base of the computer housing 1 can be kept low.

As a result of the proposed cooling apparatus for computers it is possible to place the processor 4 together with the motherboard in the cooling box 6 without any major reconfiguration work and to connect the cooling box to the active cooling unit 3 as an add-on device, in particular in the form of a subassembly unit, by way of the heat-insulating hose 3a. With the achieved cooling it is then possible to overclock the clock speed of the CPU and similar electronic components (so-called overclocking). Since the cooling in the region of the CPU takes a certain amount of time due to the circulated air quantity, the cooling apparatus is preferably used for computers operated continuously, especially network servers. By enclosing the relevant electronic components by means of the cooling box 6, the noise level (with respect to blower cooling) is also reduced substantially.

1. (Currently Amended) A cooling apparatus for computers, with a processor attached to a motherboard, which processor can be cooled off by way of an active cooling unit to temperatures below ambient temperature, especially negative temperatures, comprising:
a cooling box containing the processor and the motherboard, the cooling box made of micro-porous pressed ceramic powder on a base of metal oxides, in particular pyrogenically produced, highly dispersed silicic acid or silicon aerogel.

2. (Currently Amended) A cooling apparatus as claimed in claim 1, wherein the cooling box comprises two half-shells which define an inner hollow space.

3. (Currently Amended) A cooling apparatus as claimed in claim 2, wherein the half-shells are shaped symmetrically.

4. (Currently Amended) A cooling apparatus as claimed in claim 3, wherein the half-shells are connected by way of a film hinge and/or hooks or clips.

5. (Currently Amended) A cooling apparatus as claimed in claim 4, wherein the film hinge is formed by projecting parts of a casing.

6. (Currently Amended) A cooling apparatus as claimed in claim 5, further comprising an outlet opening for cables, and ribbon cables in particular, provided opposite of the film hinge.

7. (Currently Amended) A cooling apparatus as claimed in claim 6, wherein the outlet opening has a wave-like cross section.

8. (Currently Amended) A cooling apparatus as claimed in claim 7, further comprising a plurality of sealing rims provided along the outlet opening.

9. (Currently Amended) A cooling apparatus as claimed in claim 8, wherein the microporous pressed ceramic powder is evacuated in a substantially diffusion-tight film casing.

10. (Currently Amended) A cooling apparatus as claimed in claim 9, wherein the casing consists of a plastic material of a bag-like arrangement.

11. (New) A cooling apparatus suitable for use with a processor attached to a motherboard, allowing a processor to be cooled by an active cooling unit to temperatures below ambient temperature, comprising:
a cooling box made of micro-porous pressed ceramic powder on a base of metal oxides, formed to contain a processor and a motherboard.

12. (New) A cooling apparatus as claimed in claim 11, wherein the cooling box comprises two half-shells which define an inner hollow space.

13. (New) A cooling apparatus as claimed in claim 12, wherein the half-shells are connected by a film hinge and/or hooks or clips.

14. (New) A cooling apparatus as claimed in claim 13, wherein the cooling box further includes an outlet opening for cables, disposed opposite the film hinge.

15. (New) A cooling apparatus as claimed in claim 14, wherein the microporous pressed ceramic powder is enclosed in an evacuated, substantially diffusion-tight film casing.

16. (New) A cooling apparatus for computers, including a processor attached to a motherboard, which processor can be cooled by way of an active cooling unit to temperatures below ambient temperature, comprising:
a cooling box made of micro-porous pressed ceramic powder on a base of metal oxides, containing the processor and the motherboard, the cooling box including two half-shells which define an inner hollow space, the processor and the motherboard occupying a portion of the inner hollow space.

17. (New) A cooling apparatus as claimed in claim 16, wherein the half-shells are connected by a film hinge and/or hooks or clips.

18. (New) A cooling apparatus as claimed in claim 17, wherein the cooling box further includes an outlet opening for cables, disposed opposite the film hinge.

19. (New) A cooling apparatus as claimed in claim 18, wherein the microporous pressed ceramic powder is enclosed in an evacuated, substantially diffusion-tight plastic material in a bag-like arrangement.

20. (New) A cooling apparatus as claimed in claim 19, wherein the outlet opening has a wave-like cross section.
